(19) United States
(12) Patent Application Publication
(10) Pub. No.: US 2005/0231239 A1
(43) Pub. Date: Oct. 20, 2005

(54) Transconductance control circuit for at least one transistor in conduction

(75) Inventor: Thierry Melly, Lausanne (CH)

Correspondence Address: SUGHRUE MION, PLLC, 2100 PENNSYLVANIA AVENUE, N.W., SUITE 800, WASHINGTON, DC, 20037, US

(73) Assignee: CSEM Centre Suisse d'Electronique et de Microtechnique SA

(21) Appl. No.: 11/108,727

(22) Filed: Apr. 19, 2005

(30) Foreign Application Priority Data
Apr. 19, 2004 (EP) 04101609.8

(51) Int. Cl. H03K 5/22

(52) U.S. Cl. 327/65

(57) ABSTRACT

The control circuit (1) allows the transconductance of at least one transistor (N1, N2) in conduction to be controlled. In order to do this, the circuit includes a transconductor block (2) which includes the transistor in conduction, a bias block (3) for biasing the transconductor block, and a load block (R_{L}, R_{L′}) receiving a load current provided by the transconductor block. The bias block includes a reference resistor (R₀), so that the bias block supplies the transconductor block with at least one bias signal which depends upon the reference resistor to adjust the voltage between two current terminals of the transistor in conduction. In this manner, the transconductance value of the transistor in conduction is inversely proportional to the reference resistor value.

This application claims priority from European Patent Application No. 04101609.8 filed Apr. 19, 2004, the entire disclosure of which is incorporated herein by reference.

The invention concerns a transconductance control circuit for at least one transistor in conduction. The control circuit includes a transconductor block which includes the transistor in conduction, a bias block for biasing the transconductor block and a load block receiving a load current supplied by the transconductor block.

The use of transistors in conduction, for example of the MOS type, for making transconductor blocks, is well known in the state of the art. These transconductor blocks can be used in several technical applications, such as, for example, in direct current filters or in mixers for data signal frequency conversion stages.

Usually, the transconductance of a transistor in conduction is variable particularly as a function of the voltage difference between the drain and the source of the MOS transistor in conduction. However, it may be desired, in accordance with certain conditions required by the technical application in which the transistor in conduction is used, to ensure control of its transconductance as a function of a determined parameter. For example, via this control of the transistor's transconductance in conduction, a determined load current may be guaranteed for the load block connected to the transconductor block.

It is an object of the invention to provide a transconductance control circuit for at least one transistor in conduction such that the transconductance is controlled by a particular parameter of the circuit to obtain, for example, a fixed voltage gain of said transistor in conduction.

The invention therefore concerns a transconductance control circuit for at least one transistor in conduction, which includes the features mentioned in claim 1.

Advantageous embodiments of the circuit are defined in the dependent claims 2 to 8.

One advantage of the circuit according to the invention lies in the fact that a reference resistor, placed in the bias block, enables a bias signal to be supplied to the transconductance block, such that the voltage between the two current terminals of the transistor in conduction is adjusted. These two current terminals are, for example, the source terminal and the drain terminal of a MOS transistor. In this manner, the transconductance value becomes inversely proportional to the value of the reference resistor.

If the current of the transistor in conduction is used as a load current for a load block, which includes at least one load resistor, the transconductance control using the reference resistor enables a determined voltage gain to be obtained dependent upon a resistor ratio. This voltage gain is thus not influenced by the dispersion of the absolute value of each of the resistors, or by the temperature variation able to affect the value of the latter, which is an additional advantage. Since the control circuit can be made in CMOS technology, it is important to be free of any resistor value dispersion in order to obtain a voltage gain that is independent of the variation in resistor values.

The objects, advantages and features of the transconductance control circuit for at least one transistor in conduction will appear more clearly in the following description of embodiments illustrated by the drawings, in which:

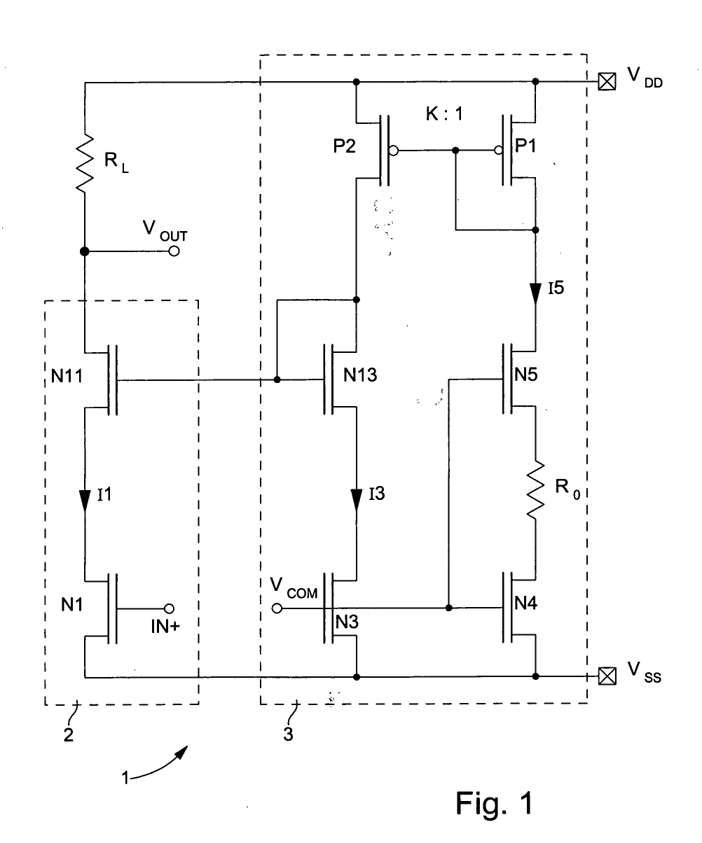

FIG. 1 shows an embodiment of a transconductance control circuit for a transistor in conduction according to the invention,

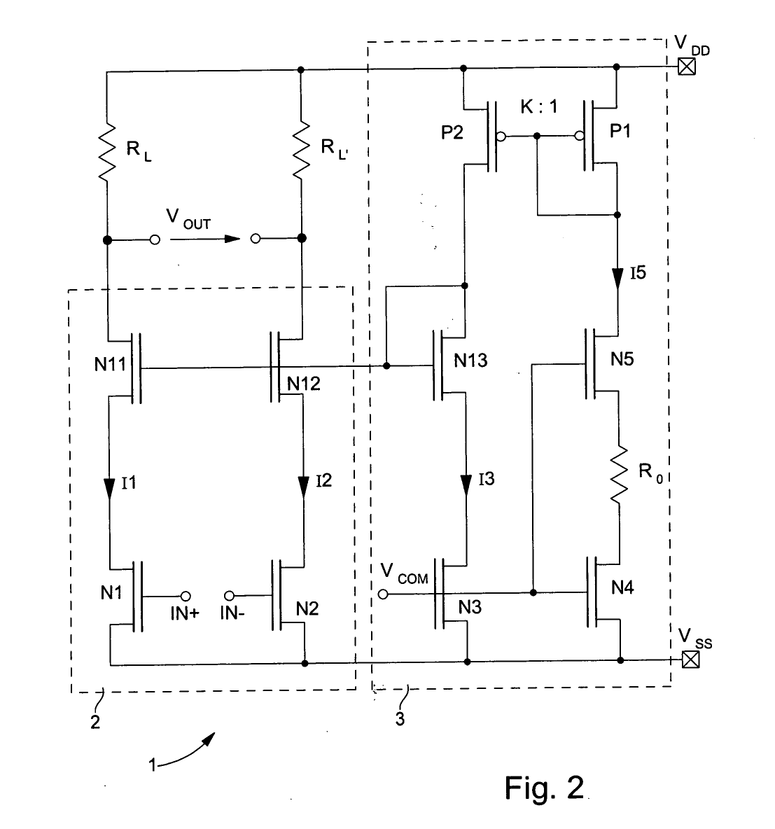

FIG. 2 shows an amplifier made using a transconductance control circuit for transistors in conduction according to the invention, and

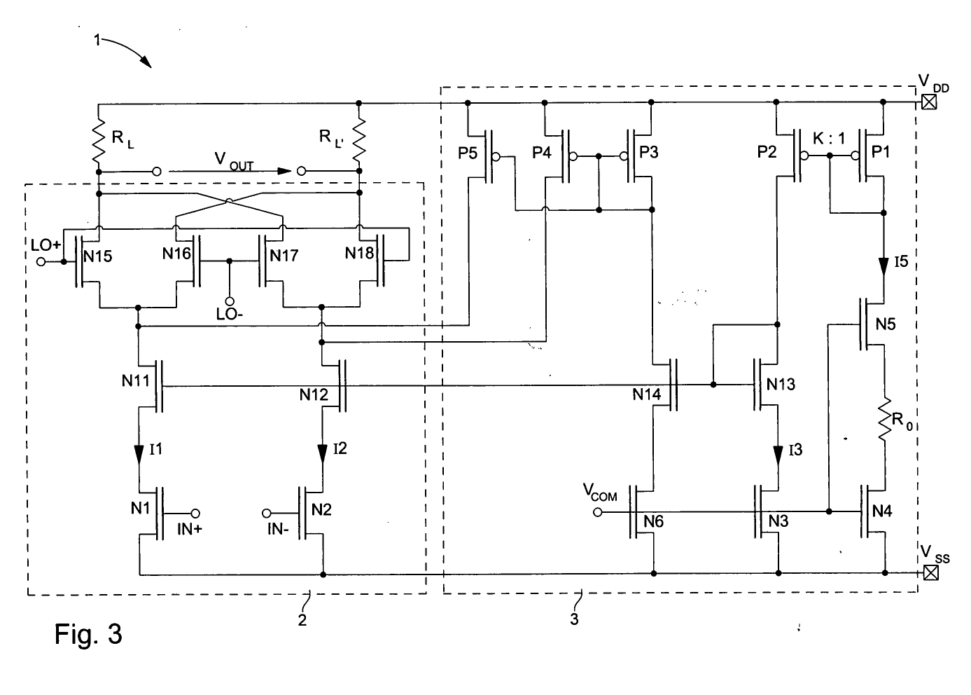

FIG. 3 shows a signal frequency conversion mixer made using the transconductance control circuit for transistors in conduction according to the invention.

In the following description, all the elements or functions of the control circuit, which are well known to those skilled in the art in this technical field will be described only in a simplified manner, particularly as regards the dimensions of each transistor. Preferably, the control circuit is made in CMOS technology, for example at 0.18 μm with transistors of a first type of conductivity N (NMOS) and a second type of conductivity P (PMOS).

FIG. 1 shows a transconductance control circuit 1 for at least one transistor in conduction according to the invention in a simple embodiment. This control circuit 1 includes a transconductor block 2, which comprises in particular the transistor in conduction, preferably of type NMOS N1, a bias block 3 for biasing the transconductor block, and a load block represented by a load resistor R_{L}. Control circuit 1 is connected via a first supply terminal V_{SS} and a second supply terminal V_{DD} to a continuous supply voltage source that is not shown. For the operation of control circuit 1, the supply voltage can be comprised between 0.9 and 1.8 V.

Transconductor block 2 is formed, in this embodiment, of the transistor in conduction N1 whose transconductance has to be adjusted and a NMOS control transistor N11 series mounted in a cascode arrangement with transistor N1. The purpose of this control transistor N11 is to adjust the voltage between the current terminals of transistor in conduction N1.

In order to do this, the source terminal of transistor in conduction N1 is connected to the first supply terminal V_{SS} which can be an earth terminal, and the drain terminal of transistor N1 is connected to the source terminal of control transistor N11. The control terminal, i.e. the gate terminal IN+ of transistor in conduction N₁ is intended to receive an alternating voltage V^{IN+} centred around a common mode voltage V_{COM}. This common mode voltage is defined hereinbefore as the transistor threshold voltage to place it, preferably, in a high inversion mode.

The gate terminal of control transistor N11 is connected to the gate terminal of an intermediate NMOS transistor N13 of bias block 3, the purpose of which is to transmit a bias signal to transconductor block 2. The gate terminal of intermediate transistor N13 is directly connected to its drain terminal to transmit the bias signal in the form of a continuous gate voltage to control transistor N11. As it will be understood in the following description, the level of this gate voltage is defined owing to a reference resistor R₀ of the bias block.

By fixing the gate voltage of control transistor N11, the voltage between the drain and the source of the transistor in conduction N1, defined as drain voltage V_{D1}, is adjusted as a function of reference resistor R₀ of bias block 3 according to the invention. The transconductance value gm of the transistor in conduction N1 is, in fact, inversely proportional to the value of reference resistor R₀.

The current delivered by the transistor in conduction passes through control transistor N11. This current will act as load current for the load resistor R_{L}, which is connected between the second supply terminal V_{DD} and the drain terminal of control transistor N11.

If, as mentioned previously, the transconductance gm is inversely proportional to resistor R₀ of bias block 3, the voltage gain of transistor N1, which is equal to the ratio V_{OUT}/V_{IN+}, is proportional to gm times R_{L} and thus, to the ratio of load resistor R_{L} to reference resistor R₀. Consequently, with this resistor ratio, a voltage gain can be controlled while providing the advantage of being independent of the absolute values of resistors R_{L} and R₀, which can vary by around 30% in CMOS technology. Moreover, this arrangement is free of the temperature variations that can affect each of the resistors, since only their ratio is taken into account.

Bias block 3, in which reference resistor R₀ is placed, includes first of all a first current mirror, which is formed of two PMOS transistors P1 and P2, whose source terminal is connected to the second supply terminal V_{DD} of the circuit. The first PMOS transistor P1 is diode mounted with the gate terminal connected to the drain terminal, and the gate terminal of the second PMOS transistor P2 is connected to the gate terminal of the first PMOS transistor. The channel width W to channel length L ratio of each transistor P1 and P2 is selected such that the current in the second transistor P2 is k times greater than the current in the first transistor P1 of the first current mirror. This factor k is preferably an integer number greater than 1, for example equal to 2.

Bias block 3 further includes two NMOS transistors N3 and N4, whose source terminal is connected to the first supply terminal V_{SS} of the circuit, and a NMOS follower transistor N5. The gate terminal of the first NMOS transistor N3 is connected to the gate terminal of the second NMOS transistor N4 so as to be biased by a common mode continuous voltage V_{COM}, which is above the threshold voltages of these NMOS transistors. These NMOS transistors N3 and N4 preferably operate in high inversion but can, also, be biased to operate in low inversion.

The gate terminal of NMOS follower transistor N5 is connected to the gate terminal of the first and second NMOS transistors N3 and N4, and its drain terminal is connected to the drain terminal of the first PMOS transistor P1. Reference resistor R₀ is connected between the source terminal of NMOS transistor N5 and the drain terminal of the second NMOS transistor N4 in a reference branch. Transistor N5 has the peculiarity of being biased so as to form a voltage follower, i.e. with a shift of threshold voltage V_{TN}.

The drain terminal of the second PMOS transistor P2 is connected to the drain terminal of the diode mounted intermediate NMOS transistor N13. The source terminal of this intermediate transistor is connected to the drain terminal of the first NMOS transistor N3 in a mirrored current branch.

In order to understand the relation between the transconductance gm of the transistor in conduction N1 and the resistor R₀ of the bias block, current formulae in transistor N1 and in transistors N3 and N5 are given below:
I1=n·β₁·((V_{COM} +V_{IN+}(t)−V_{TN})/n−V_{D1}/2)·V_{D1} with β₁=μ·Cₒₓ·W₁/L₁
gm1=d(I1)/d(V_{IN+})=β₁·V_{D1}
I3=n·β₃·((V_{COM}−V_{TN})/n−V_{D3}/2)·V_{D3} with β₃=μCₒₓ·W₃/L₃
I3=k·I5≈k·(V_{COM}−V_{TN}−V_{D4})/R₀ with V_{D4}=n·V_{D3}/2
where V_{D1} and V_{D3} are the drain voltages of transistors N1 and N3, V_{TN} is the threshold voltage, V_{COM} and V_{IN+}(t) are respectively the common mode voltage and the alternating voltage around V_{COM} across terminal IN+. The slope factor n, mobility μ, capacitance COX, channel width W and channel length L are parameters of the transistors or CMOS technolgy used.

Transconductance gm of NMOS transistor N1 is equal to β₁·V_{D1}, which means that by keeping drain voltage V_{D1} at a determined value by biasing control transistor N11 via reference resistor R₀, this transconductance gm is dependent upon resistor R₀. For a voltage V_{IN+} equal to 0, it can be deduced, by the formulae given hereinbefore, that the drain voltage V_{1D} of transistor N1 is equal to the drain voltage V_{D3} of transistor N3. Consequently, the drain voltage V_{D1} of transistor N1 is equal to k/(R₀-β₃), the consequence of which is that the transconductance gm is equal to k·β₁/R₀·β₃. This proves that the value of transconductance gm is really inversely proportional to the value of reference resistor R₀.

In order to give an order of magnitude for the currents and resistors of such a control circuit, current I1 can have a value of 100 μA at V_{IN+}=0, whereas current I3 can have a value of 10 μA and current I5 can have a value of 5 μA by adapting the width to length ratio of the transistor channel. The reference resistor R₀ is equal, for example, to 50 kΩ, whereas load resistor R_{L} is equal to 5 kΩ being made in an identical manner to the reference resistor. The common mode voltage V_{COM} can be located between 50 to 300 mV above threshold voltage V_{TN}.

FIG. 2 shows an amplifier which is made using the transconductance control circuit for transistors in conduction 1. It should be noted that all the same elements of the circuit which were described in FIG. 1 bear the same reference signs. Consequently, for the sake of simplification, the description of such elements will not be repeated.

One of the differences of the control circuit shown in FIG. 2 is that transconductor block 2 includes two NMOS transistors in conduction N1 and N2 respectively connected to two NMOS control transistors N11 and N12 in a cascode arrangement. The source terminal of the two transistors in conduction N1 and N2 is connected to the first supply terminal V_{SS} of the circuit, and the gate terminal of the two control transistors N11 and N12 is connected to the gate terminal of the intermediate NMOS transistor N13 of bias block 3. In this manner, the voltage between the source and the drain of each transistor in conduction N1 and N2 is adjusted by a gate voltage applied across the gate terminal of the NMOS control transistors N11 and N12 owing to reference resistor R₀. The transconductance value gm of each transistor in conduction N1 and N2 is thus inversely proportional to the value of reference resistor R₀ as described previously.

An additional load resistor R_{L′} is added in the load block between the second supply terminal V_{DD} and the drain terminal of control transistor N12. The load current I2 of a mean value equivalent to I1 determined by transistor N2 passes through control transistor N12, and load resistor R_{L′}. The output voltage V_{OUT} from the amplifier is supplied to the connection of each load resistor R_{L} and R_{L′} and of the drain terminal of each control transistor N11 and N12.

In this embodiment relating to an amplifier, the alternating voltage V_{IN} around the common mode voltage V_{COM} applied to the terminal IN− of the transistor in conduction N2 is the reverse of the alternating voltage V_{IN+} around the common mode voltage V_{COM} applied to the terminal IN+of the transistor in conduction N1. Consequently, in this differential version, the load voltage of each resistor R_{L} and R_{L′}, is also of reversed polarity relative to a mean voltage when V_{IN+} and V_{IN} have a value of 0.

FIG. 3 shows finally a mixer for signal frequency conversion made using the transconductance control circuit for transistors in conduction. As previously, all of the same elements of the circuit that were described in FIGS. 1 and 2 bear the same reference signs. For the sake of simplification, the description of such elements will not be repeated.

In this embodiment in the form of a mixer, the transconductor block 2 further includes two differential pairs of NMOS transistors N15, N16, N17 and N18 placed between load resistors R_{L} and R_{L′} and the drain terminal of control transistors N11 and N12. The source terminal of the NMOS transistors of the first pair N15 and N16 is connected to the drain terminal of the first control transistor N11 and the source terminal of the NMOS transistors of the second pair N17 and N18 is connected to the drain terminal of the second control transistor N12.

Load resistor R_{L} is connected between the second supply terminal V_{DD} of the circuit and the drain terminal of the first transistor N15 of the first pair and of the second transistor N17 of the second pair. Load resistor R_{L′} is connected between the second supply terminal of the circuit and the drain terminal of the second transistor N16 of the first pair and of the first transistor N18 of the second pair. The gate terminal LO+ of the first transistors N15 and N18 of the first and second pairs is controlled by a first alternating voltage from a first voltage source, whereas the gate terminal LO− of the second transistors N16 and N17 of the first and second pairs is controlled by a second alternating voltage from a second voltage source. The first alternating voltage is of identical shape to the second alternating voltage but phase shifted by 180°.

Currents I1 and I2 are alternating currents due to the variation in voltages V_{IN+} and V_{IN} respectively applied across terminals IN+ and IN− of the transistors in conduction N1 and N2. Alternating voltages V_{IN+} and V_{IN-} around common mode voltage V_{COM} are of identical shape, but phase shifted by 180° from each other. For a signal frequency conversion mixer, voltages V_{IN+} and V_{IN-} applied across the gate terminals of transistors N1 and N2 can define base band data signals at 25 kHz. However, the alternating voltages applied across terminals LO+ and LO− can define signals of sinusoidal shape having a frequency of the order of 48 MHz or 96 MHz for example. With this mixture of different frequency signals, output voltage V_{OUT} includes intermediate frequency data signals of the order of 48 MHz or 96 MHz.

Bias block 3 of this mixer further includes a second current mirror. This second current mirror is formed of three PMOS transistors P3, P4 and P5 whose source terminal is connected to the second supply terminal V_{DD} of the circuit. The first PMOS transistor P3 of the second mirror is diode mounted with a gate terminal connected to a drain terminal to receive a current from a third NMOS transistor N6 through a second intermediate NMOS transistor N14. The source terminal of transistor N6 is thus connected to the first supply terminal V_{SS}, and its gate terminal is connected to the gate terminal of transistors N3, N4 and N5. The drain terminal of transistor N6 is connected to the source terminal of the second intermediate NMOS transistor N14, whose gate terminal is connected to the gate terminal of transistor N13 and whose drain terminal is connected to the drain terminal of PMOS transistor P3.

The second and third PMOS transistors P4 and P5 of the second mirror have a gate terminal connected to the gate terminal of the first PMOS transistor P3. Transistors P4 and P5 each supply a steady attenuation current of the load current respectively to the drain terminal of the first and second control transistors N11 and N12 of transconductor block 2. In this way, it is possible to attenuate the load current supplied to each load resistor R_{L} and R_{L′}.

From the description that has just been given, multiple variants of the transconductance control circuit for at least one transistor can be designed by those skilled in the art without departing from the scope of the invention defined by the claims. The configuration of the control circuit can be accomplished, inversely, by replacing the PMOS transistors by NMOS transistors and the NMOS transistors by PMOS transistors and by placing each load resistor on the side of the first supply terminal of the circuit. One could also envisage replacing each MOS transistor by bipolar transistors.

1. A transconductance control circuit for at least one transistor in conduction, the circuit including:
a transconductor block, which includes the transistor in conduction provided with a control terminal and two current terminals.
a bias block for biasing the transconductor block by at least one bias signal, the bias block including a reference resistor in a reference branch,
a load block receiving a load current provided by the transconductor block,
wherein the transconductor block includes at least one control transistor series connected in a cascode arrangement with the transistor in conduction, one control terminal of the control transistor receiving the bias signal in the form of a continuous voltage whose the level depends on the reference resistor so that the control transistor adjusts the voltage between the two current terminals of the transistor in conduction such that the transconductance value of the transistor in conduction is inversely proportional to the reference resistor value.

2. The control circuit according to claim 1, wherein the load block includes at least one load resistor passed through by a load current coming from a current delivered by the transistor in conduction so that the ratio of the load resistor to the reference resistor defines a controlled voltage gain independent upon the absolute values of resistors and temperature variations.

3. The control circuit according to claim 2, the circuit being supplied with voltage by a continuous voltage source by first and second supply terminals, wherein the control transistor and the transistor in conduction are MOS transistors of the same type of conductivity P or N, wherein the transistor in conduction includes a source terminal connected to a first supply terminal of the circuit and a drain terminal connected to a source terminal of the control transistor and wherein the bias signal is applied across the gate terminal of the control transistor in the form of a gate voltage dependent upon the reference resistor to adjust the voltage between the source and the drain of the transistor in conduction.

4. The control circuit according to claim 1, the circuit being made with MOS transistors of a first type of conductivity P or N or of a second type of conductivity N or P, wherein the bias block includes a first current mirror which is formed of two MOS transistors of a first type of conductivity whose one source terminal of the MOS transistors is connected to a second supply terminal of the circuit, the first MOS transistor of the first mirror being diode mounted with a gate terminal connected to a drain terminal and the second MOS transistor of the first mirror having a gate terminal connected to the gate terminal of the first MOS transistor, wherein the bias block includes at least two transistors of a second type of conductivity, whose one source terminal of the MOS transistors is connected to a first supply terminal of the circuit, a gate terminal of the first MOS transistor of the second type being connected to a gate terminal of the second MOS transistor of the second type in order to be biased by a common mode continuous voltage, wherein a MOS follower transistor of a second type of conductivity includes a gate terminal connected to the gate terminal of the first and second MOS transistors of the second type and a drain terminal connected to the drain terminal of the first MOS transistor of the first type diode mounted, and wherein the reference resistor is connected between a source terminal of the MOS follower transistor and a drain terminal of the second MOS transistor of the second type.

5. The control circuit according to claim 4, wherein a diode mounted intermediate MOS transistor of a second type of conductivity includes a drain terminal connected to a drain terminal of the second MOS transistor of the first mirror and a source terminal connected to a drain terminal of the first MOS transistor of the second type, wherein the second MOS transistor of the first mirror supplies a current k times greater than the first MOS transistor of the first mirror, k being an integer number greater than 1, and wherein a gate terminal of the intermediate MOS transistor is connected to a gate terminal of the MOS control transistor of the second type.

6. The control circuit according to claim 4, wherein the transconductor block includes two MOS transistors in conduction of the second type, respectively connected to two MOS control transistors of the second type in a cascode arrangement, the source terminal of the two transistors in conduction being connected to a first supply terminal of the circuit and the gate terminal of the two control transistors being connected to the gate terminal of the intermediate MOS transistor of the bias block so that the voltage between the source and the drain of each transistor in conduction is adjusted by a gate voltage applied across the gate terminal of the intermediate MOS transistor such that the transconductance value of each transistor in conduction is inversely proportional to the reference resistor value.

7. The control circuit according to claim 6, the circuit forming an alternating signal mixer, wherein the transconductor block includes two differential pairs of MOS transistors of the second type, a source terminal of the MOS transistors of the first pair being connected to the drain terminal of the first control transistor to receive a first alternating current supplied by the first transistor in conduction and a source terminal of the MOS transistors of the second pair being connected to the drain terminal of the second control transistor to receive a second reversed alternating current phase shifted by 180° in relation to the first alternating current, supplied by the second transistor in conduction, wherein the load block includes a first resistor, which is connected between a second supply terminal of the circuit and a drain terminal of the first transistor of the first pair and of the second transistor of the second pair and a second resistor, which is connected between the second supply terminal of the circuit and a drain terminal of the second transistor of the first pair and of the first transistor of the second pair, wherein the gate terminal of the first transistors of the first and second pairs is controlled by a first alternating voltage from a first voltage source, and wherein the gate terminal of the second transistors of the first and second pairs is controlled by a second alternating voltage from a second voltage source phase shifted by 180° in relation to the first alternating voltage to deliver to the load resistor terminals an alternating output voltage whose frequency is dependent upon the frequency of the first and second load currents and the frequency of the first and second alternating voltages.

8. The control circuit according to claim 7, wherein the bias block includes a second current mirror which is formed of three MOS transistors of a first type of conductivity whose a source terminal of the transistors is connected to the second supply terminal of the circuit, the first MOS transistor of the second mirror being diode mounted with a gate terminal connected to a drain terminal to receive a current equivalent to the current of the first transistor of the second type, and wherein the second and third MOS transistors of the second mirror have a gate terminal connected to the gate terminal of the first MOS transistor of the second mirror to each provide an attenuation current respectively to the drain terminal of the first and second control transistors of the transconductor block to attenuate the load current supplied to each load resistor.
